(19) United States
(12) Patent Application Publication
(10) Pub. No.: US 2006/0091412 A1
(43) Pub. Date: May 4, 2006

(54) Polarized LED

(76) Inventors: John A. Wheatley, Lake Elmo, MN (US); Catherine A. Leatherdale, St. Paul, MN (US); Andrew J. Ouderkirk, Woodbury, MN (US)

Correspondence Address: 3M INNOVATIVE PROPERTIES COMPANY, PO BOX 33427, ST. PAUL, MN, 55133-3427, US

(21) Appl. No.: 10/977,582

(22) Filed: Oct. 29, 2004

(51) Int. Cl. H01L 33/00

(52) U.S. Cl. 257/98

(57) ABSTRACT

A solid state light source includes an LED die that generates light of two polarization states. A medium is provided at or near an emitting surface of the LED die that preferentially reflects one polarization state back into the LED die and preferentially transmits the other polarization state out of the LED die, thus providing a solid state light source whose light output is at least partially polarized. Recycling of light within the LED die together with polarization conversion mechanisms can enhance efficiency and brightness of the polarized output.

### FIELD OF THE INVENTION

The present invention relates to solid state light sources. The invention further relates to light sources that utilize a semiconductor band gap structure for light generation, particularly light emitting diodes (LEDs).

### BACKGROUND

LEDs are a desirable choice of light source in part because of their relatively small size, low power/current requirements, high speed, long life, robust packaging, variety of available output wavelengths, and compatibility with modern circuit boards. These characteristics may help explain their widespread use over the past few decades in a multitude of different end use applications. Improvements to LEDs continue to be made in the areas of efficiency, brightness, and output wavelength, further enlarging the scope of potential end-use applications.

### BRIEF SUMMARY

The present application discloses light sources that utilize at least one LED die. The die has at least one emitting surface and generates light of a first and second polarization state. Light source constructions are disclosed that preferentially couple light of a given polarization state out of the LED die emitting surface. Light source constructions are also disclosed that preferentially reflect light of a given polarization state back into the LED die. In some cases, a birefringent material is provided in optical contact with the emitting surface of the LED die. In some cases a reflecting means such as a reflective polarizer is provided at the LED die emitting surface. Light recirculation within the LED die, and polarization conversion mechanisms, are also disclosed to enhance the luminous output and brightness of the LED package for the selected polarization state.

These and other aspects of the invention will be apparent from the detailed description below. In no event, however, should the above summaries be construed as limitations on the claimed subject matter, which subject matter is defined solely by the attached claims, as may be amended during prosecution.

### BRIEF DESCRIPTION OF THE DRAWINGS

Throughout the specification, reference is made to the appended drawings, where like reference numerals designate like elements, and wherein:

FIG. 1 is a fragmentary schematic sectional view of a portion of a polarized LED package;

FIG. 2 is a fragmentary schematic sectional view of a portion of another polarized LED package; and

FIGS. 3-7 are schematic sectional views of further polarized LED packages.

### DETAILED DESCRIPTION OF THE ILLUSTRATIVE EMBODIMENTS

Some of the emerging LED applications involve systems in which the light must be polarized at some point in the light path. Since most light sources, including LEDs, emit substantially non-polarized light, the insertion of a separate polarizing device is typically required. In some systems, the polarizer simply transmits one polarization state (about half, at best, of the light source output) and absorbs, scatters, or otherwise blocks the other polarization state. In these systems, more than half of the light source luminous output is wasted. In other systems, the light source illuminates a separate extended cavity, and the polarizer is arranged on one side of the cavity to not only transmit one polarization state of originally incident light, but to reflect the other polarization state. The cavity provides recycling by reflection and conversion of one polarization state to the other, such that the system utilizes somewhat more than half of the light source output.

It would be desirable to have available for systems designers a compact, packaged LED light source that efficiently emits polarized light, without the need for an optical cavity separate from the packaged LED.

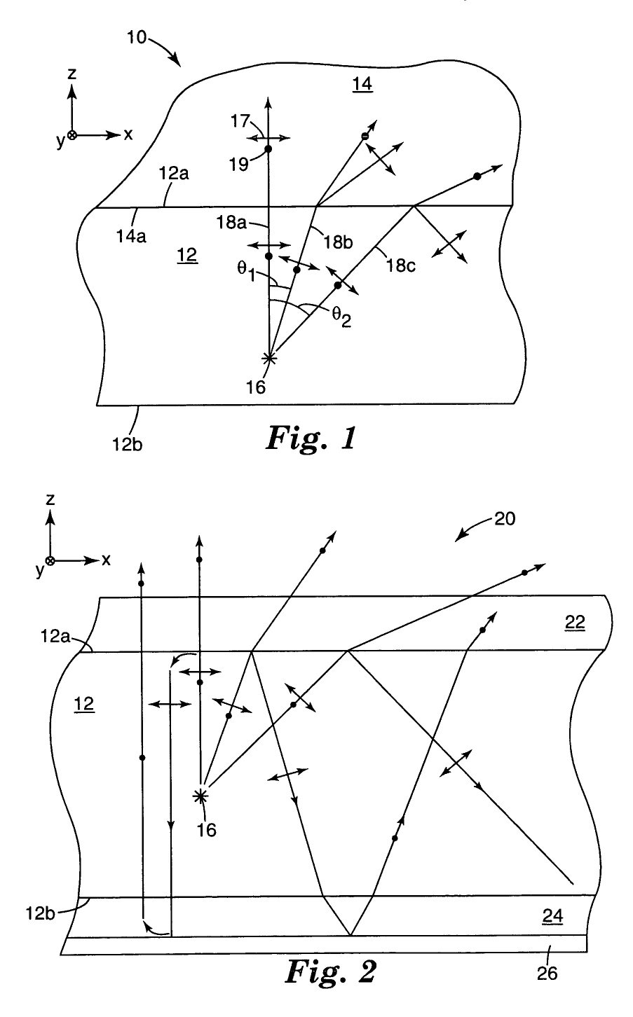

In FIG. 1, a portion of an LED package 10 includes an LED die 12 mounted on a header or other mount (not shown). The die 12 is depicted generically for simplicity, but the reader will understand that it can include conventional design features as are known in the art. For example, the LED die 12 can include distinct p- and n-doped semiconductor layers, substrate layers, buffer layers, and superstrate layers. A primary emitting surface 12a and a bottom surface 12b are shown to be flat and parallel, but other configurations are also possible. Side surfaces (not shown in FIG. 1) of the LED die can be flat and perpendicular to the top and bottom surfaces 12a, 12b to provide the die with a simple rectangular shape in cross-section, but other known configurations are also contemplated, e.g., angled side surfaces forming an inverted truncated pyramid shape. Electrical contacts to the LED die are also not shown for simplicity, but can be provided on any of the surfaces of the die as is known. In exemplary embodiments the die has two contacts both disposed at the bottom surface 12b of the die, such as is the case with “flip chip” LED die designs. Further, the mount to which the die 12 is connected can serve as a support substrate, electrical contact, heat sink, and/or reflector cup.

LED package 10 also includes an optical layer 14 having an input surface 14a that is in optical contact with emitting surface 12a of the LED die. “Optical contact” in this regard refers to the surfaces being spaced close enough together (including but not limited to being in direct physical contact) that the refractive index properties of the optical layer 14 control or influence total internal reflection of at least some light propagating within the LED die. Importantly, optical layer 14 is made of a birefringent material so that it can produce at least a partial separation of two different polarization states of light at the emitting surface 12a of the die. Referring to the x-y-z coordinate system shown, the optical layer 14 can have, for example, a refractive index nₓ for light polarized along the x-direction, and a substantially different refractive index n_{y} for light polarized along the y-direction. If n_{die} refers to the refractive index of the LED die (or that portion of the LED die immediately adjacent the emitting surface 12a), then in exemplary embodiments the magnitude of n_{die}−n_{y}, for example, is as small as possible, while the magnitude of n_{die}−nₓ, is as large as possible. This condition will usually but not always mean that n_{die}≧n_{y}≧nₓ, since n_{die} is generally higher than the refractive indices of most convenient birefringent optical materials. The light rays shown in FIG. 1 as being emitted by a localized source 16 within LED die 12 exemplify the condition n_{die}>n_{y}>nₓ. The localized source represents an infinitesimal volume within the active area of the LED junction, and it emits light of all polarizations. In relation to a selected x-y-z reference frame, the source 16 emits both linear p-polarized light, whose electric field vector is parallel to the x-z plane, shown as a transverse double-sided arrow 17 on the respective light rays, and s-polarized light, whose electric field vector is parallel to the y-z plane, shown as a dot 19 on the respective light rays. Light ray 18a, emitted in a direction normal (i.e., orthogonal) to the emitting surface 12a, passes undeflected into optical layer 14, for both s- and p-polarizations. Another light ray 18b emitted in a direction θ₁ relative to the surface normal experiences double refraction at the emitting surface 12a, with the s-polarized component being transmitted into optical layer 14 at an angle of refraction that is larger than θ₁ but smaller than the refraction angle of the s-polarized component. Still another light ray 18c is emitted in a direction θ₂ relative to the surface normal that is greater than the critical angle sin⁻¹(nₓ./n_{die}) for p-polarized light but less than the critical angle sin⁻¹(n_{y}./n_{die}) for s-polarized light, hence the p-polarized component is totally internally reflected back into the LED die 12 but the s-polarized component crosses the interface and is transmitted to the optical layer 14.

The reader will appreciate from the foregoing that more s-polarized light emitted by the source 16 is coupled out of the LED die than p-polarized light, since a greater angular wedge of s-polarized light is transmitted to the optical layer 14. Thus, optical layer 14 has the effect of preferentially extracting from the LED die light whose electric field vector is aligned with, in this case, the high refractive index y-direction of the birefringent material, compared to light whose electric field vector is aligned with the low refractive index x-direction of the birefringent material. This result does not change if one also takes into account Fresnel reflections of the various light rays at interfaces between different materials. A similar conclusion is also reached if the birefringent material of optical layer 14 is circularly or elliptically birefringent, as occurs for example in cholesteric materials, rather than linearly birefringent materials. In that event, the circular or elliptical polarization state associated with the higher refractive index will be preferentially extracted from the LED die. Stated more generally, the polarization state associated with the refractive index of the birefringent material that is closest to n_{die} will be preferentially extracted from the LED die, and the polarization state associated with the refractive index of the birefringent material that is farthest from n_{die} will be preferentially reflected back into the LED die.

The preferential extraction of one polarization state from the die can be amplified where the LED die has low enough losses and high enough surface reflectivities to support substantial recycling of light within the LED die. Polarization converting means coupled to one or more of the LED surfaces can also boost overall efficiency, as discussed below.

For maximum separation of the two polarization states, the birefringence of layer 14 is as large as possible, preferably at least 0.1 or even about 0.2 or more. Suitable birefringent materials include uniaxially oriented polyethylene terephthalate, uniaxially oriented polyethylene naphthalate, calcite, and aligned liquid crystals and liquid crystal polymers. Liquid crystals and liquid crystal polymers can be aligned by rubbing the emitting surface 12a in one direction with a felt, abrasive, or other material, then coating the die surface with a liquid crystal or liquid crystal polymers. Alternatively, the die can be coated with an alignment layer such as polyvinyl alcohol or other material, which is then rubbed and coated with liquid crystalline materials. Since alignment layers will commonly have a relatively low refractive index, it can be beneficial for this application that the alignment coating be optically thin, meaning less than about the wavelength of the LED emission in vacuum. The alignment layer can also be fabricated by coating the die with a suitable thin layer of a photosensitive material and exposing the coating to polarized ultraviolet light. A suitable process is described in U.S. Pat. No. 6,610,462 (Chien et al.). Suitable liquid crystal materials include nematic phase and cholesteric materials.

For linear birefringent materials, it is advantageous to arrange the minimum and maximum polarization axes (the axes along which the refractive index of the birefringent material is minimum and maximum, respectively) to lie in a plane parallel to the LED emitting surface 12a. Other orientations of the polarization axes can also be made to provide selective coupling of one polarization state out of the LED die, but the polarization efficiency, or degree of polarization of the light output, may be reduced.

The optical layer 14 can take many physical forms. It can be or comprise a physically thin (but optically thick, at least on the order of one-tenth, one-half, or even one wavelength of light) layer of material. It can be formed in place on the LED emitting surface, as with a liquid resin that is applied to the LED and then cured, or formed separately as a free-standing film, molded element, shaped element, or the like, and then brought into optical contact with the emitting surface. It can have simple flat parallel input and output major surfaces, or the output surface can be curved to provide focusing or collimation. It can have an input surface that is oversized, matched to, or undersized relative to the LED emitting surface. It can have the shape of a simple or compound tapered element, or can be included in multiple tapered elements, as described in co-filed and commonly assigned U.S. Patent Application “High Brightness LED Package With Compound Optical Element(s)”, Attorney Docket No. 60218US002, and co-filed and commonly assigned U.S. Patent Application “High Brightness LED Package With Multiple Optical Elements”, Attorney Docket No. 60219US002, each of which is incorporated herein by reference in its entirety. It can be the only layer, or one of multiple layers, making up a workpiece that is subsequently shaped into a plurality of optical elements by a precisely patterned abrasive, as described in more detail in co-filed and commonly assigned U.S. Patent Application “Process For Manufacturing Optical and Semiconductor Elements”), Attorney Docket No. 60203US002, and co-filed and commonly assigned U.S. Patent Application “A Process For Manufacturing A Light Emitting Array”), Attorney Docket No. 60204US002, each of which is incorporated herein by reference in its entirety.

FIG. 2 shows another polarized LED package 20, where the simple birefringent optical layer 14 has been replaced with a reflective polarizer 22. Reflective polarizer 22 may be in optical contact with LED emitting surface 12a. Alternatively, another layer can be disposed between reflective polarizer 22 and emitting surface 12a. Such other layer preferably has a refractive index less than that of the LED die 12 (or that portion of LED die 12 proximate surface 12a). As with LED die 12, reflective polarizer 22 is depicted generically, but is intended to comprise polarizers with multiple components such as a multilayer optical stack, an example of which is Dual Brightness Enhancement Film (DBEF) sold by 3M Company, St. Paul, Minn., or a multitude of individual conductive stripes present in known wire grid polarizers. Suitable wire grid polarizers are described in U.S. Pat. No. 6,243,199 (Hansen et al.) and U.S. Patent Publication 2003/0227678 (Lines et al.), both of which are incorporated herein by reference in their entirety. Optionally, the wire grid polarizer can also be covered with a protective coating. Suitable protective coatings include ceramics, glasses, and polymers. Reflective polarizer 22 transmits a first polarization state and not only blocks but also reflects a second polarization state orthogonal to the first state, both for normally incident light and obliquely incident light. (“Orthogonal” in this regard, used in reference to polarization states, is not intended to be limited to linear polarization states that differ by 90 degrees, but also encompasses other mathematically independent polarization states such as, for example, left-circular versus right-circular polarization states.) If absorptive and scattering losses within the LED die are low, light recycling within the LED die can cause some light of the second polarization state to be converted to the first polarization state.

Such conversion can be facilitated by applying a polarization converting layer, such as a quarter-wave plate, to at least one surface of the LED die. In FIG. 2, polarization converting layer 24 can comprise such a quarter-wave plate. Suitable quarter wave plates can be constructed from, for example, sapphire, quartz, lithium niobate, and calcite. Thus, for a light ray that traverses the thickness of layer 24, one polarization becomes retarded relative to the other polarization by about one-fourth of the wavelength of light or a higher order, i.e., about 0.25λ, or 1.25λ, 2.25λ, and so forth. The layer 24 can be provided on other outer surfaces of the LED die as well, e.g., on the side surfaces and emitting surface of the die. As an alternative to using a quarter-wave plate to convert one polarization to the other, the bottom surface 12b or other surfaces of the LED die can be roughened to provide some polarization conversion upon reflection from a scattering surface. Suitable scattering surfaces include abraded, roughened, or etched surfaces. A high reflectivity layer 26 is also provided in FIG. 2. Layer 26 has a high reflectivity for all polarization states, such as is provided by a metal coating or multilayer interference mirror stack. As shown in FIG. 2, light of the second polarization state traveling toward the bottom surface 12b of the die passes through polarization converting layer 24 two times and is reflected by reflective layer 26, thus being converted to a light ray of the first polarization state which can then escape from the emitting surface 12a. The combination of reflecting, at the LED emitting surface, light of the unwanted polarization state, recycling light within the LED die, and converting at least some of the unwanted polarization state light to the desired polarization state, enhances both the luminous output and the brightness of the LED package with regard to light of the desired (first) polarization state.

The polarization converting layer and high reflectivity layers 24, 26, respectively, can equally be applied to the LED package 10 of FIG. 1.

As mentioned above, suitable reflective polarizers 22 include but are not limited to multilayer birefringent polarizers, cholesteric reflective polarizers, and wire grid polarizers. See, for example, U.S. Pat. No. 5,882,774 (Jonza et al.), “Optical Film”, and PCT Publication WO 01/18570 (Hansen et al.), “Improved Wire-Grid Polarizing Beam Splitter”, each of which is incorporated herein by reference in its entirety. A wire grid polarizer can have the additional benefit of being useable as an electrical contact for the LED die.

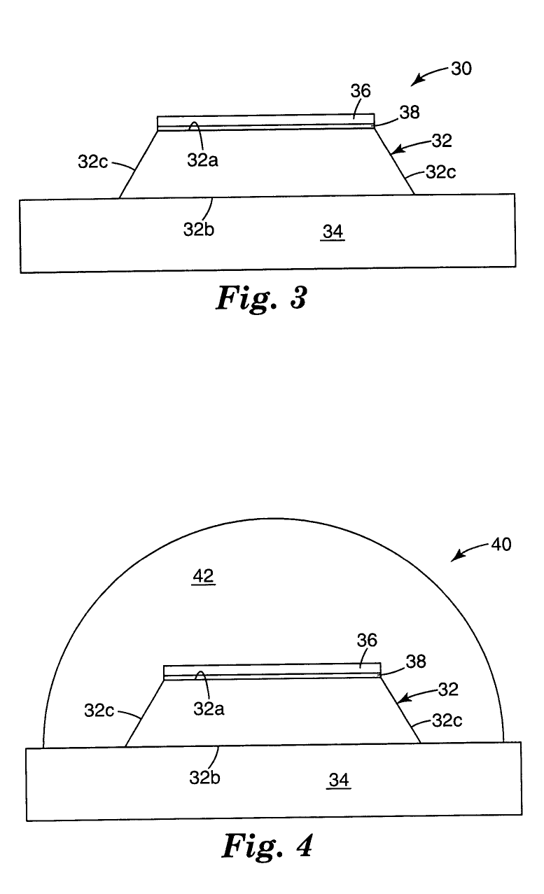

Turning now to FIG. 3, we see there an LED package 30 comprising an LED die 32 attached to a header or mount 34. LED die 32 is similar to LED die 12, and has a front emitting surface 32a, a bottom surface 32b, and side surfaces 32c. The side surfaces 32c are shown to be angled, but this is not necessary and other side surface configurations are also contemplated. LED package 30 also includes a reflective polarizer 36, which transmits a first polarization state of light to the outside environment and preferentially reflects an orthogonal second polarization state of light back into the LED die 32. In the embodiment of FIG. 3, a polarization converting layer in the form of a quarter-wave plate 38 is provided between the reflective polarizer and LED emitting surface 32a.

FIG. 4 illustrates an additional LED package 40 made by adding a transparent optical element 42 to surround and encapsulate the LED die and other layers atop the mount 34 in FIG. 3. The optical element can increase the luminous output of the LED package by reducing reflections at the top or major exposed surface of the reflective polarizer. Optical element 42 can be formed using a resin or other liquid-phase material and curing the resin or otherwise hardening the material to provide rigidity and protection in a highly transparent, low scattering medium. In such case, the optical element will generally have a substantially isotropic refractive index. In exemplary embodiments, the refractive index of element 42 can be from about 1.4 to about 2. In alternative but related embodiments where a simple layer of birefringent material is substituted for reflective polarizer 36, the refractive index of element 42 is preferably substantially equal to the extraordinary refractive index of the birefringent material.

The birefringent layers and/or reflective polarizers described above can also be incorporated into embodiments that utilize tapered optical elements, such tapered elements being capable of capturing a wider angular wedge of emitted light and collimating (at least partially) such light into a narrower angular wedge of light.

For example, FIG. 5 depicts an LED package 50 in which a tapered optical element 52 is in optical contact with the emitting surface 12a of the LED die 12. Side surfaces 12c of the LED die are shown perpendicular to the top and bottom LED die surfaces, but they can also be angled or have other configurations as is known. Optical element 52 has an input surface 52a that is oversized relative to LED emitting surface 12a, and reflective tapered side surfaces 52c leading to output surface 52b. Element 52 can be composed of a highly birefringent material and have a substantially unitary construction. For example, element 52 can be composed entirely of calcite. Alternatively, element 52 can have a two-part construction (see dividing line 53), with an input portion comprising input surface 52a composed of a layer of birefringent material, or a reflective polarizer, and an output portion comprising output surface 52b composed of a conventional transparent optical glass, ceramic, plastic, or other material. The optical element can further be bonded by conventional means to at least the LED emitting surface, or can be held in position without being mechanically bonded thereto in order to decouple mechanical forces such as stresses between the two components. In that regard, reference is made to co-filed and commonly assigned U.S. Patent Application “LED Package With Non-Bonded Optical Element”, Attorney Docket No. 60216US002, which is incorporated herein by reference in its entirety. The optical element can further be thermally coupled to a heat sink to assist in drawing heat out of the emitting surface of the LED die, as described in co-filed and commonly assigned U.S. Patent Application “LED Package With Front Surface Heat Extractor”, Attorney Docket No. 60296US002, also incorporated herein by reference in its entirety.

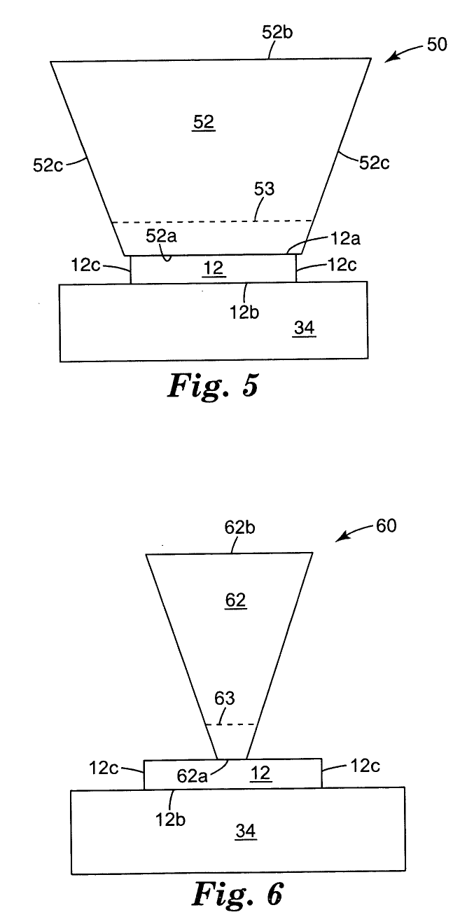

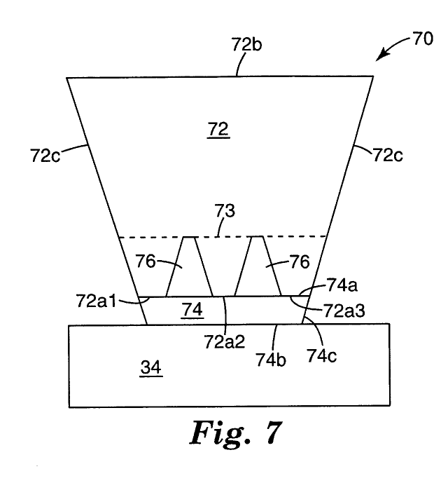

FIGS. 6 and 7 show still further embodiments that incorporate tapered elements. LED package 60 in FIG. 6 utilizes a tapered optical element 62 whose input surface 62a is smaller than the emitting surface 12a of the LED die. Benefits of this arrangement, in which the LED emitting surface is surrounded by a patterned low refractive index layer (e.g. a gap), are described further in co-filed and commonly assigned U.S. Patent Application “High Brightness LED Package”, Attorney Docket No. 60217US002, which is incorporated herein by reference in its entirety. Element 62 can be composed of a highly birefringent material and have a substantially unitary construction. For example, element 62 can be composed entirely of calcite. Alternatively, element 62 can have a two-part construction (see dividing line 63), with an input portion comprising input surface 62a composed of a layer of birefringent material, or a reflective polarizer, and an output portion comprising output surface 62b composed of a conventional transparent optical glass, ceramic, plastic, or other material. In that regard, reference is made to co-filed and commonly assigned U.S. Patent Application “High Brightness LED Package With Compound Optical Element(s)”, Attorney Docket No. 60218US002, incorporated herein by reference in its entirety.

In FIG. 7, an LED package 70 includes an LED die 74 on mount 34. The package also includes a tapered optical element 72 in optical contact with an emitting surface 74a of the die. Tapered optical element 72 has a lower portion (see dividing line 73) comprising multiple smaller tapered elements having multiple input surfaces 72a1, 72a2, 72a3, and an upper portion comprising output surface 72b. The smaller tapered elements define gaps 76 therebetween. Reference is made to co-filed and commonly assigned U.S. Patent Application “High Brightness LED Package With Multiple Optical Elements”, Attorney Docket No. 60219US002, incorporated herein by reference in its entirety. Reflective side surfaces 72c reflect some light between the input surfaces 72a1, 72a2, 72a3 and the output surface 72b. Element 72 can be composed of a highly birefringent material and have a substantially unitary construction. For example, element 72 can be composed entirely of calcite. Alternatively, element 72 can have a two-part construction, where the smaller tapered elements of the lower portion are composed of a birefringent material, or a reflective polarizer, and the upper portion is composed of a conventional transparent optical glass, ceramic, plastic, or other material.

Glossary of Selected Terms

“Brightness”: the luminous output of an emitter or portion thereof per unit area and per unit solid angle (steradian).
“Light emitting diode” or “LED”: a diode that emits light, whether visible, ultraviolet, or infrared. The term as used herein includes incoherent (and usually inexpensive) epoxy-encased semiconductor devices marketed as “LEDs”, whether of the conventional or super-radiant variety.
“LED die”: an LED in its most basic form, i.e., in the form of an individual component or chip made by semiconductor wafer processing procedures. The component or chip can include electrical contacts suitable for application of power to energize the device. The individual layers and other functional elements of the component or chip are typically formed on the wafer scale, the finished wafer finally being diced into individual piece parts to yield a multiplicity of LED dies.

Various modifications and alterations of the invention will be apparent to those skilled in the art without departing from the spirit and scope of the invention. It should be understood that the invention is not limited to illustrative embodiments set forth herein.

What is claimed is:

1. A light source, comprising:
an LED die that generates light of a first and second polarization state, the die having an emitting surface; and
a birefringent material coupled to the LED die such that light of the first polarization state is preferentially coupled out of the emitting surface.

2. The light source of claim 1, wherein the birefringent material has an input surface in optical contact with the emitting surface of the LED die.

3. The light source of claim 1, wherein the birefringent material has a refractive index mismatch for the first and second polarization states of at least about 0.05.

4. A light source, comprising:
an LED die that generates light of a first and second polarization state, the die having an emitting surface; and
reflecting means coupled to the LED die for preferentially reflecting the second polarization state back into the LED die.

5. The light source of either claim 1 or 4, further comprising a polarization converting layer coupled to the LED die.

6. The light source of claim 5, wherein the polarization converting layer comprises a wave plate.

7. The light source of claim 5, wherein the polarization converting layer comprises a scattering surface.

8. The light source of claim 4, wherein the reflecting means comprises a body of birefringent material proximate the emitting surface.

9. The light source of claim 8, wherein the body has an input surface proximate the emitting surface, and further has an output surface and at least one reflective side surface between the input and output surfaces.

10. The light source of claim 8, wherein the birefringent material comprises calcite.

11. The light source of claim 4, wherein the reflecting means comprises a reflective polarizer proximate the emitting surface.

12. The light source of claim 11, wherein the reflective polarizer comprises a wire grid.

13. The light source of claim 11, wherein the reflective polarizer comprises a multilayer optical film.

14. The light source of claim 11, wherein the reflective polarizer comprises cholesteric material.
